(19) United States
(12) Patent Application Publication
(10) Pub. No.: US 2015/0124179 A1
(43) Pub. Date: May 7, 2015

(54) DISPLAY DEVICE AND METHOD OF MANUFACTURING THE SAME

(71) Applicant: Samsung Electronics Co., Ltd., Suwon-si (KR)

(72) Inventors: Jae-Hun KO, Seoul (KR); Kyung-Hoon KIM, Seoul (KR)

(21) Appl. No.: 14/509,397

(22) Filed: Oct. 8, 2014

(30) Foreign Application Priority Data
Nov. 4, 2013 (KR) 10-2013-0133012

(51) Int. Cl. G02F 1/1335; H01L 27/32; G02F 1/1333

(52) U.S. Cl. CPC G02F 1/1335; G02F 1/13338; H01L 27/323
USPC 349/12; 445/24; 349/84

(57) ABSTRACT

A display device and a method of manufacturing the same are provided. The display device includes a window part having a three-dimensional pattern on a front surface thereof instead of a pattern film layer, a color printing layer formed on a rear surface of the window part, a shielding printing layer formed on a rear surface of the color printing layer, and a display part provided on a rear surface of the shielding printing layer.

### CROSS-REFERENCE TO RELATED APPLICATION(S)

This application claims the benefit under 35 U.S.C. §119(a) of a Korean patent application filed on Nov. 4, 2013 in the Korean Intellectual Property Office and assigned Serial number 10-2013-0133012, the entire disclosure of which is hereby incorporated by reference.

### TECHNICAL FIELD

The present disclosure relates to a display device including a display screen protecting window and a method of manufacturing the same.

### BACKGROUND

In general, a window is installed to protect a screen of a display device, such as a Liquid Crystal Display (LCD), which is used in a portable communication device, a Portable Multimedia Player (PMP), a Personal Digital Assistant (PDA), an MP3 player, or a Television (TV), and is also called a window part. In addition to a main object to protect a screen of a display device, the window is used for advertising and promotion of a manufacturer by printing various emblems, logos, letters, or patterns on a surface of the screen.

In recent years, due to rapid development of multimedia technologies and display technologies, there has been a revolution in display devices of a portable communication devices and a touch screen panel has been increasingly adopted in portable communication devices. Because a resistive touch sensor according to the related art uses two sensors to provide location information with a touch pressure, a film is attached to an upper end of a window provided in a portable communication device. However, a capacitive Touch Screen Panel (TSP), which is has been more widely used recently, informs a user of location information of a point at which electric charges are discharged when a touch occurs.

FIG. 1 is a view showing a configuration of a display device according to the related art.

Referring to FIG. 1, the display device is manufactured by cutting a window 1 formed of tempered glass, attaching a pattern film layer 3 on a rear surface of the window 1 by using a bonding layer 2, attaching a touch screen panel 4 on a rear surface of the pattern film layer 3, and attaching a display part (LCD) 5 on a rear surface of the touch screen panel 4. Then, a fingerprint preventing layer (AF coating) (not shown) is coated on a front surface of the window.

The pattern film layer 3 includes a film layer (PET film) 3a, a deposition layer 3b having a pattern on a surface thereof, a color printing layer 3c provided on a rear surface of the deposition layer 3b, and a shielding layer 3d provided on a rear surface of the color printing layer 3c. A Ultra-Violet (UV) molding 6 is provided between the film layer 3a and the deposition layer 3b such that the deposition layer 3b may be attached to a rear surface of the film layer 3a.

However, because the display device including a window according to the related art is manufactured by combining a pattern film layer with a window, the price of the product increases due to the pattern film layer whose manufacturing process is complex, and the pattern film layer may be wetted and floated due to fine bubbles or an external appearance of the pattern film layer may become unattractive.

In addition, by combining the pattern film layer with the window formed of tempered glass, permeability of the product may be lowered. Further, because a color of the product may be realized by attaching a color printing layer on a rear surface of the pattern film layer with a deposition layer, a color deviation of the product may occur.

For example, as shown in FIG. 1, because the deposition layer is provided on an upper surface of the color printing layer, the natural color of the color printing layer does not appear.

Further, because the pattern film layer is combined with the window at a high temperature according to the related art, the pattern film layer is laterally changed, contracted, and deformed.

In addition, because a hybrid cover glass integrated (G1F) TSP and a cover glass integrated (G2) TSP correspond to a method of depositing a one-layered Indium Tin Oxide (ITO) pattern film on a rear surface of a window to pattern the ITO pattern film, and attaching a sheet of ITO pattern film forming the remaining axis, realizing a pattern on a rear surface of the window is difficult and a pattern film layer cannot be applied to various types of touch screen panels.

Further, issues regarding heat emission are constantly troubling as increasing amounts of heat are transferred from the interior of the electronic product to the window.

Accordingly, an apparatus and manufacturing process by which a display device can be manufactured without using a pattern film layer according to the related art are desired to overcome the problems and disadvantages.

The above information is presented as background information only to assist with an understanding of the present disclosure. No determination has been made, and no assertion is made, as to whether any of the above might be applicable as prior art with regard to the present disclosure.

### SUMMARY

Aspects of the present disclosure are to address at least the above-mentioned problems and/or disadvantages and to provide at least the advantages described below. Accordingly, an aspect of the present disclosure is to provide a display device in which a structure and a manufacturing process can be simplified, and a method of manufacturing the same.

Another aspect of the present disclosure is to provide a display device which realizes a depth and a three-dimensional feeling without using a pattern film layer according to the related art by forming a three-dimensional pattern on a front surface of a window part instead of a pattern film layer according to the related art, reduces manufacturing costs and the thickness of a product, prevents a color deviation of the product generated by the pattern film layer according to the related art, simplifies a manufacturing process of the product by eliminating a process for the pattern film layer according to the related art, reduces a processing time, prevents bubbles, floating of the pattern film layer according to the related art, and a change of the external shape of the display device which may have been generated during processing of the pattern film layer according to the related art, and prevents a lateral change, a contraction, a short circuit, and a rainbow phenomenon, and a method of manufacturing the same.

Another aspect of the present disclosure is to provide a display device which can be applied to various types of touch screen panels by forming a three-dimensional pattern not on a rear surface but a front surface of a window part, and a method of manufacturing the same.

Another aspect of the present disclosure is to provide a display device which further realizes a depth and a three-dimensional feeling by forming a three-dimensional pattern on a rear surface of a window part instead of an pattern film layer according to the related art, reduces manufacturing costs and the thickness of a product, simplifies the manufacturing process, further prevents bubbles, floating, and a change of an external shape generated during processing of the pattern film layer according to the related art, and further prevents a transverse change, a contraction, a short circuit, and a rainbow phenomenon, and a method of manufacturing the same.

Another aspect of the present disclosure is to provide a display device which further realizes a depth and a three-dimensional feeling by forming a three-dimensional pattern on both the front and rear surfaces of a window part instead of an pattern film layer according to the related art, reduces manufacturing costs and the thickness of a product, simplifies the manufacturing process, further prevents bubbles, floating, and a change of an external shape generated during processing of the pattern film layer according to the related art, and further prevents a transverse change, a contraction, a short circuit, and a rainbow phenomenon, and a method of manufacturing the same.

In accordance with another aspect of the present disclosure, a display device is provided. The display device includes a window part having a three-dimensional pattern on a front surface thereof, a color printing layer formed on a rear surface of the window part, a shielding printing layer formed on a rear surface of the color printing layer, and a display part provided on a rear surface of the shielding printing layer.

In accordance with another aspect of the present disclosure, a method of manufacturing a display device is provided. The method includes forming a three-dimensional pattern on a front surface of a window part, forming a color printing layer on a rear surface of the window part, forming a shielding printing layer on a rear surface of the color printing layer, and providing a display device on a rear surface of the shielding printing layer.

In accordance with another aspect of the present disclosure, a display device is provided. The display device includes a window part having a three-dimensional pattern on a front surface thereof, a deposition layer provided on a rear surface of the window part, a color printing layer formed on a rear surface of the deposition layer, a shielding printing layer formed on a rear surface of the color printing layer, and a display part provided on a rear surface of the shielding printing layer.

In accordance with another aspect of the present disclosure, a method of manufacturing a display device is provided. The method includes forming a three-dimensional pattern on a front surface of a window part, forming a deposition layer on a rear surface of the window part, forming a color printing layer on a rear surface of the deposition layer, forming a shielding printing layer on a rear surface of the color printing layer, and providing a display device on a rear surface of the shielding printing layer.

In accordance with another aspect of the present disclosure, a display device is provided. The display device includes a window part having a three-dimensional pattern on a rear surface thereof, a deposition layer provided on a rear surface of the window part, a color printing layer formed on a rear surface of the deposition layer, a shielding printing layer formed on a rear surface of the color printing layer, and a display part provided on a rear surface of the shielding printing layer.

In accordance with another aspect of the present disclosure, a method of manufacturing a display device is provided. The method includes forming a three-dimensional pattern on a rear surface of a window part, forming a deposition layer on a rear surface of the window part, forming a color printing layer on a rear surface of the deposition layer, forming a shielding printing layer on a rear surface of the color printing layer, and providing a display device on a rear surface of the shielding printing layer.

In accordance with another aspect of the present disclosure, a display device is provided. The display device includes a window part having three-dimensional patterns on the front and rear surfaces thereof, a deposition layer provided on a rear surface of the window part, a color printing layer formed on a rear surface of the deposition layer, a shielding printing layer formed on a rear surface of the color printing layer, and a display part provided on a rear surface of the shielding printing layer.

In accordance with another aspect of the present disclosure, a method of manufacturing a display device is provided. The method includes forming three-dimensional patterns on the front and rear surfaces of a window part, forming a deposition layer on a rear surface of the window part, forming a color printing layer on a rear surface of the deposition layer, forming a shielding printing layer on a rear surface of the color printing layer, and providing a display device on a rear surface of the shielding printing layer.

In accordance with another aspect of the present disclosure, a display device is provided. The display device includes a window part having a three-dimensional pattern on a rear surface thereof, a color printing layer formed on a rear surface of the window part, a shielding printing layer formed on a rear surface of the color printing layer, and a display part provided on a rear surface of the shielding printing layer.

In accordance with another aspect of the present disclosure, a method of manufacturing a display device is provided. The method includes forming a three-dimensional pattern on a rear surface of a window part, forming a color printing layer on a rear surface of the window part, forming a shielding printing layer on a rear surface of the color printing layer, and providing a display device on a rear surface of the shielding printing layer.

In accordance with another aspect of the present disclosure, a display device is provided. The display device includes a window part having a three-dimensional pattern on the front and rear surfaces thereof, a color printing layer formed on a rear surface of the window part, a shielding printing layer formed on a rear surface of the color printing layer, and a display part provided on a rear surface of the shielding printing layer.

In accordance with another aspect of the present disclosure, a method of manufacturing a display device is provided. The method includes forming three-dimensional patterns on the front and rear surfaces of a window part, forming a color printing layer on a rear surface of the window part, forming a shielding printing layer on a rear surface of the color printing layer, and providing a display device on a rear surface of the shielding printing layer.

Other aspects, advantages, and salient features of the disclosure will become apparent to those skilled in the art from the following detailed description, which, taken in conjunction with the annexed drawings, discloses various embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a view showing a configuration of a display device according to the related art;

FIG. 2 is a view showing a configuration of a display device according to a first embodiment of the present disclosure;

FIG. 3 is a flowchart showing a method of manufacturing a display device according to the first embodiment of the present disclosure;

FIG. 4 is a view showing a configuration of a display device according to a second embodiment of the present disclosure;

FIG. 5 is a flowchart showing a method of manufacturing a display device according to the second embodiment of the present disclosure;

FIG. 6 is a view showing a configuration of a display device according to a third embodiment of the present disclosure;

FIG. 7 is a flowchart showing a method of manufacturing a display device according to the third embodiment of the present disclosure;

FIG. 8 is a view showing a configuration of a display device according to a fourth embodiment of the present disclosure;

FIG. 9 is a flowchart showing a method of manufacturing a display device according to the fourth embodiment of the present disclosure;

FIG. 10 is a view showing a configuration of a display device according to a fifth embodiment of the present disclosure;

FIG. 11 is a flowchart showing a method of manufacturing a display device according to the fifth embodiment of the present disclosure;

FIG. 12 is a view showing a configuration of a display device according to a sixth embodiment of the present disclosure; and

FIG. 13 is a flowchart showing a method of manufacturing a display device according to the sixth embodiment of the present disclosure.

The same reference numerals are used to represent the same elements throughout the drawings.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

According to various embodiments of the present disclosure, an electronic device may include communication functionality. For example, an electronic device may be a smart phone, a tablet Personal Computer (PC), a mobile phone, a video phone, an e-book reader, a desktop PC, a laptop PC, a netbook PC, a Personal Digital Assistant (PDA), a Portable Multimedia Player (PMP), an mp3 player, a mobile medical device, a camera, a wearable device (e.g., a Head-Mounted Device (HMD), electronic clothes, electronic braces, an electronic necklace, an electronic appcessory, an electronic tattoo, or a smart watch), and/or the like.

According to various embodiments of the present disclosure, an electronic device may be a smart home appliance with communication functionality. A smart home appliance may be, for example, a television, a Digital Video Disk (DVD) player, an audio, a refrigerator, an air conditioner, a vacuum cleaner, an oven, a microwave oven, a washer, a dryer, an air purifier, a set-top box, a TV box (e.g., Samsung HomeSync™, Apple TV™, or Google TV™), a gaming console, an electronic dictionary, an electronic key, a camcorder, an electronic picture frame, and/or the like.

According to various embodiments of the present disclosure, an electronic device may be a medical device (e.g., Magnetic Resonance Angiography (MRA) device, a Magnetic Resonance Imaging (MRI) device, Computed Tomography (CT) device, an imaging device, or an ultrasonic device), a navigation device, a Global Positioning System (GPS) receiver, an Event Data Recorder (EDR), a Flight Data Recorder (FDR), an automotive infotainment device, a naval electronic device (e.g., naval navigation device, gyroscope, or compass), an avionic electronic device, a security device, an industrial or consumer robot, and/or the like.

According to various embodiments of the present disclosure, an electronic device may be furniture, part of a building/structure, an electronic board, electronic signature receiving device, a projector, various measuring devices (e.g., water, electricity, gas or electro-magnetic wave measuring devices), and/or the like that include communication functionality.

According to various embodiments of the present disclosure, an electronic device may be any combination of the foregoing devices. In addition, it will be apparent to one having ordinary skill in the art that an electronic device according to various embodiments of the present disclosure is not limited to the foregoing devices.

According to various embodiments of the present disclosure, an electronic device may comprise a display device.

FIG. 2 is a view showing a configuration of a display device according to a first embodiment of the present disclosure.

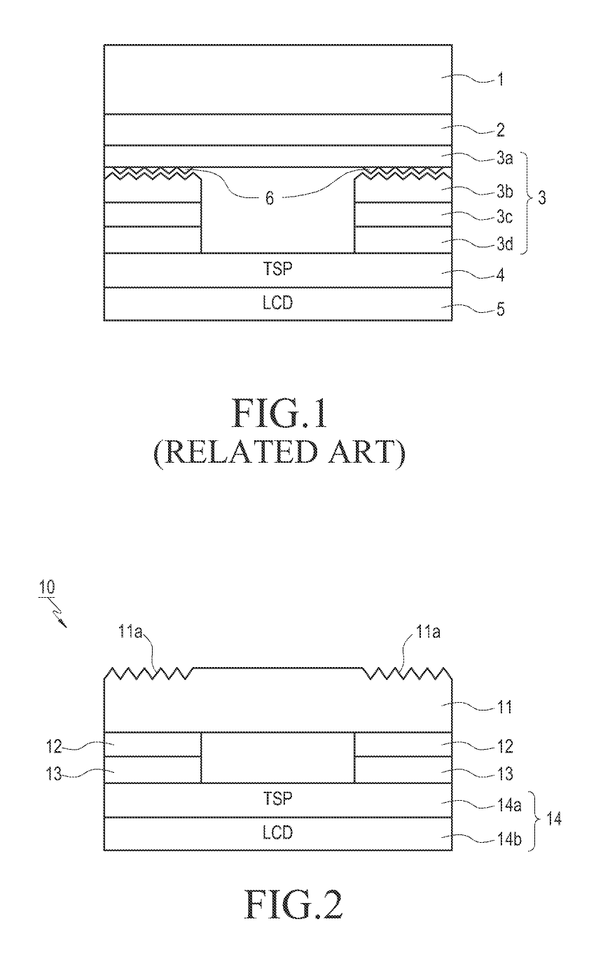

Referring to FIG. 2, the display device 10 includes a window part 11 formed of a tempered glass material, a color printing layer 12, a shielding printing layer 13, and a display part 14. According to various embodiments of the present disclosure, a three-dimensional pattern 11a may be formed on a front surface of the window part 11 by etching the window part 11 by using a laser instead of an pattern film layer 3 according to the related art (see FIG. 1). The color printing layer 12 is formed on a rear surface of the window part 11 such that the window part 11 may emit a luxurious and soft feeling by providing the window part 11 and the three-dimensional pattern 11a with various colors. The shielding printing layer 13 is formed on a rear surface of the color printing layer 12 to support the color printing layer 12 and the three-dimensional pattern 11a. The display part 14 is provided on a rear surface of the color printing layer 12 and on a lower surface of the window part 11 such that a screen of the display part 14 may be protected by the window part 11.

The display part 14 may be any one of a Liquid Crystal Display (LCD) 14b including a touch screen panel 14a and an LCD 14b without the touch screen panel 14a. According to various embodiments of the present disclosure, the LCD 14b including the touch screen panel 14a will be described as an example.

The touch screen panel 14a may be any one of a film electrode type (GFF) Touch Screen Panel (TSP), a hybrid cover glass integrated (G1F) TSP, a cover glass integrated (G2) TSP, an On-Cell Touch Active Matrix Organic Light Emitting Diode (AMOLED) (OCTA) TSP, and/or the like.

The film electrode type (GFF) TSP corresponds to a method of attaching two sheets of Indium Tin Oxide (ITO) patterns to a window part for the X and Y axis of a touch screen panel for recognizing a contact location of a finger.

The hybrid cover glass integrated (G1F) TSP corresponds to a method of depositing a one-layered ITO pattern film on a rear surface of a window part (e.g., at a temperature of 230 degrees or higher), patterning the ITO pattern film, and attaching one sheet of ITO pattern film to form the remaining axis.

The cover glass integrated (G2) TSP corresponds to a method of depositing a two-layered X and Y axis ITO pattern film on a rear surface of a window to realize a touch sensor (e.g., deposited at a high temperature of 230 degrees or higher).

The OCTA corresponds to a method of directly depositing an ITO pattern film on an active organic diode based display (AMOLED) along the X and Y axes to realize a touch sensor.

Although the touch screen panels 14a disclosed earlier will be described as an example in the embodiment of the present disclosure, various embodiments of the present disclosure are not limited thereto. For example, a touch screen panel 14a having another configuration may be applied.

According to the embodiment of the present disclosure, among the above-described touch screen panels 14a, the cover glass integrated (G2) TSP 14a will be described as an example.

In this way, by forming a three-dimensional pattern 11a on a front surface of the window part 11 through etching instead of forming a pattern film layer 3 according to the related art (see FIG. 1), the depth and three-dimensional feeling of the product may be realized, an external design of the product may become appealing, manufacturing costs of the product may be reduced, and the manufacturing process of the product may simplified and processing time may be reduced as separate pattern film layer attaching process according to the related art is not necessary. In addition, by forming a three-dimensional pattern 11a on a front surface of a window part 11 instead of on a rear surface of the window part 11, various types of touch screen panels 14a may be applied in addition to the touch screen panels 14a disclosed earlier.

According to various embodiments of the present disclosure, three-dimensional pattern 11a may have a saw-tooth shape having ridges and furrows and a zigzag pattern, and/or the like. Of course, other shapes and patterns may be applied as the three-dimensional pattern 11a in addition to the disclosed shapes and patterns.

In this way, because the window according to the related art (see FIG. 1) has a linear plane, heat is not properly emitted from a product.

Thus, according to various the embodiments of the present disclosure, by forming the three-dimensional pattern 11a having a saw-tooth shape and a zigzag, pattern, and/or the like instead of a linear plane on a front surface of the window part 11, heat may be easily emitted, dissipated, and radiated from a product due to a wide surface section and accordingly a heat emission problem of the product can be improved.

It can be seen from a general heat transfer equation of heat emission (Q)=Heat transfer coefficient (H)*Area (A)*dt (temperature difference) that an increase in a cross-section of a product may improve heat emission and lower a temperature of the product.

For example, a surface of the window part 11 may have an isosceles triangle three-dimensional pattern 11a to widen the surface of the window part 11 due to the two areas of the triangle. For example, when a surface of the window according to the related art (see FIG. 1) is formed simply linearly, the surface of the window cannot be wide.

As described above, the window part 11 may be formed of tempered glass. Materials other than tempered glass may be applicable as the material of the window part 11. For example, the material of the window part 11 may be reinforced plastic, reinforced acryl, polycarbonate, and/or the like.

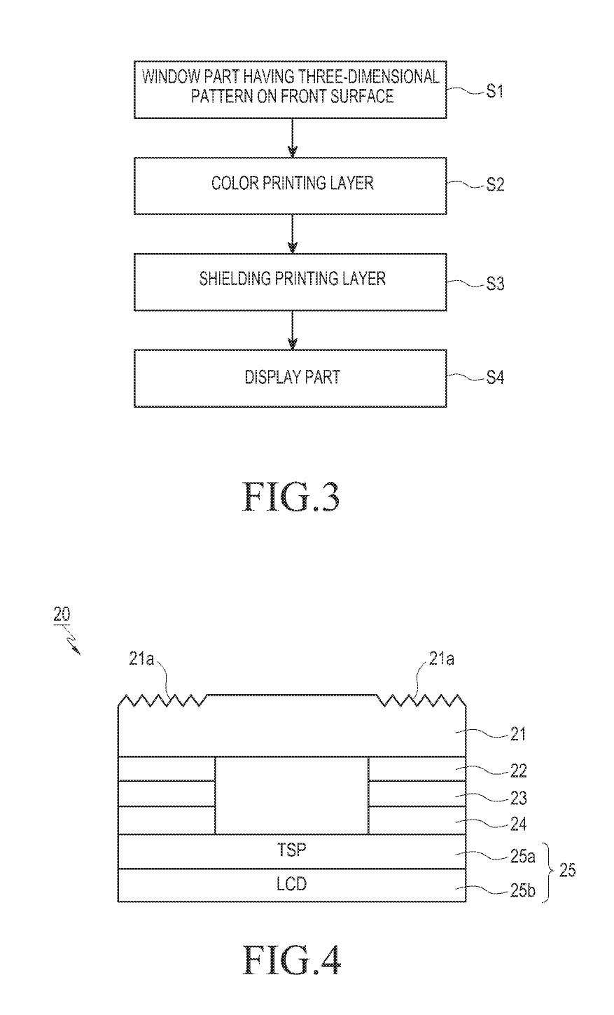

FIG. 3 is a flowchart showing a method of manufacturing a display device according to the first embodiment of the present disclosure.

Referring to FIG. 3, a window part 11 formed of tempered glass is manufactured.

At operation S1, a window part 11 having a three-dimensional pattern on the front surface thereof is formed. For example, the three-dimensional pattern 11a is formed on a front surface of the window part 11 through etching instead of a pattern film layer according to the related art.

According to various embodiments of the present disclosure, the three-dimensional pattern 11a may have a saw-tooth shape having ridges and furrows and a zigzag pattern, and/or the like. For example, a surface of the window part 11 may have an isosceles triangle three-dimensional pattern 11a to widen the surface of the window part 11 due to the two areas of the triangle, making emission of heat of the product possible (or otherwise improved in relation to the related art). For example, because a surface of a window according to the related art is simply linear, the surface of the window cannot be formed widely and thus heat cannot be easily emitted from the product.

At operation S1, a color printing layer 12 is formed. The color printing layer 12 is formed on a rear surface of the window part 11 having the three-dimensional pattern 11a.

At operation S2, a shielding printing layer 13 is formed. The shielding printing layer 13 is formed on a rear surface of the printing layer 12.

At S4 a display part 14 is formed. A touch screen panel 14a of a display part 14 is formed on a rear surface of the shielding printing layer 13.

The display part 14 is formed of an LCD 14b including a touch screen panel 14a, and the touch screen panel 14a may be any one of a film electrode type (GFF) TSP, a hybrid cover glass integrated (G1F) TSP, a cover glass integrated (G2) TSP, an OCTA touch screen panel, and/or the like.

The cover glass integrated (G2) TSP corresponds to a method of depositing a two-layered X and Y axis ITO pattern film on a rear surface of a window at a high temperature of 230 degrees or higher to realize a touch.

For example, because the window part 11 and the touch screen panel 14a are attached to each other at a high temperature in the cover glass integrated (G2) TSP, a pattern film layer 3 according to the related art (see FIG. 1) is transversely changed, contracted, and short-circuited due to high temperature heat and a shape thereof is changed.

Because there is no such pattern film layer 3 according to the related art in the embodiment of the present disclosure, the above-mentioned disadvantages do not occur when the window part 11 and the touch screen panel 14a are attached to each other at a high temperature. Thus, the embodiment of the present disclosure may be applied to various types of touch screen panels 14a.

In this way, according to the display device including a window 1 (see FIG. 1) having a pattern film layer 3 according to the related art (see FIG. 1), a window manufacturing process is difficult and the pattern film layer manufactured through a complex manufacturing process is necessary, increasing manufacturing costs.

Thus, according to various embodiments of the present disclosure, by forming a three-dimensional pattern 11a functioning as the pattern film layer 3 according to the related art (see FIG. 1) on a front surface of the window part 11 instead, the pattern film layer 3 according to the related art (see FIG. 1) is not unnecessary, making reduction in manufacturing costs of a product and simplification of a manufacturing process of the product possible.

Hereinafter, a display device according to a second embodiment of the present disclosure will be described with reference to FIG. 4. In a description of the display device according to the second embodiment of the present disclosure, the same configurations as those of the display device according to the first embodiment of the present disclosure will be omitted and only differences between the second embodiment of the present disclosure and the first embodiment of the present disclosure will be described.

FIG. 4 is a view showing a configuration of a display device according to a second embodiment of the present disclosure.

Referring to FIG. 4, a configuration of the display device 20 will be described. The display device 20 includes a window part 21 formed of tempered glass, a deposition layer 22, a color printing layer 23, a shielding printing layer 24, and a display part 25. A three-dimensional pattern 21a may be formed on a front surface of the window part 21 by etching the window part 21 by using a laser instead of a pattern film layer 3 according to the related art (see FIG. 1). The deposition layer 22 is formed between the window part 21 and the color printing layer 23 such that the color printing layer 23 is deposited on a rear surface of the window part 21. The color printing layer 23 is formed on a rear surface of the deposition layer 22 such that the window part 21 may emit a luxurious and soft feeling by providing the window part 21 and the three-dimensional pattern 21a with various colors. The shielding printing layer 24 is formed on a rear surface of the color printing layer 23 to support the color printing layer 23 and the three-dimensional pattern 21a. The display part 25 is provided on a rear surface of the color printing layer 23 and on a lower surface of the window part 21 such that a screen of the display part may be protected by the window part 21.

For example, the display part may be any one of an LCD 25b including a touch screen panel 25a and an LCD 25b without the touch screen panel 25a. According to the embodiment of the present disclosure, the LCD 25b including the touch screen panel 25a will be described as an example.

The touch screen panel 25a may be any one of a film electrode type (GFF) TSP, a hybrid cover glass integrated (G1F) TSP, a cover glass integrated (G2) TSP, an OCTA touch screen panel, and/or the like.

Because detailed operations of the disclosed touch screen panels 25a are the same as those of the first embodiment of the present disclosure, a description thereof will be omitted.

According to the embodiment of the present disclosure, among the above-described touch screen panels 25a, the cover glass integrated (G2) TSP 14a will be described as an example.

According to various embodiments of the present disclosure, by forming the three-dimensional pattern 21a through etching on a front surface of the window part 21 instead of the pattern film layer 3 according to the related art (see FIG. 1) and attaching the color printing layer 23 on a rear surface of the window part 21 by the deposition layer 22, a deep and three-dimensional feeling can be realized, an external design of the product can become more appealing, and manufacturing costs can be reduced. Further, because a process for the pattern film layer 3 according to the related art (see FIG. 1) is not necessary, a manufacturing process of the product can be simplified and processing time can be reduced. In addition, by forming the three-dimensional pattern 21a on a front surface of the window part 21 instead of a rear surface of the window part 21, the method can be applied to various types of touch screen panels 25a other than the disclosed touch screen panel 25a.

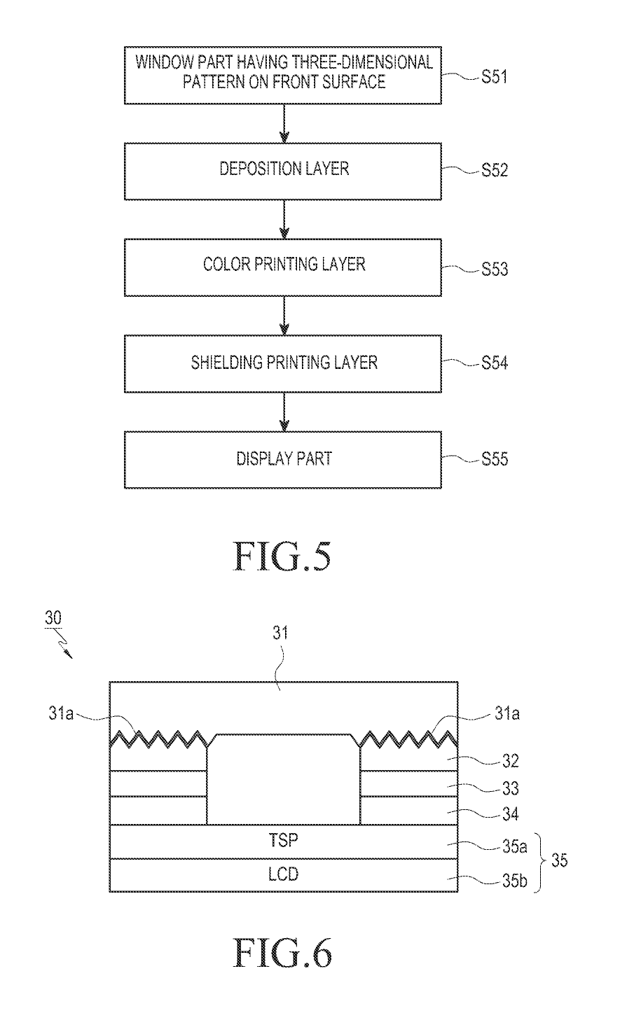

FIG. 5 is a flowchart showing a method of manufacturing a display device according to the second embodiment of the present disclosure.

Referring to FIG. 5, a method of manufacturing the display device will be described. A window part 21 formed of tempered glass is manufactured.

At operation S51, a window having a three-dimensional pattern 21 on a front surface thereof is formed. The three-dimensional pattern 21a is formed on a front surface of the window part 21 through etching instead of the pattern film layer 3 according to the related art (see FIG. 1). Thus, forming the pattern film layer according to the related art separately is not necessary.

According to various embodiments of the present disclosure, the three-dimensional pattern 21a may have a saw-tooth shape having ridges and furrows and a zigzag pattern, and/or the like.

At operation S52, a deposition layer 22 is formed. The deposition layer 22 is formed on a rear surface of the window part 21 having the three-dimensional pattern 21a.

At operation S53, a color printing layer 23 is formed. The color printing layer 23 is attached on a rear surface of the deposition layer 22.

For example, the deposition layer 22 may be additionally formed and the color printing layer 23 may be easily attached in the various embodiments of the present disclosure.

At operation S54, a shielding printing layer 24 is formed. The shielding printing layer 24 is formed on a rear surface of the printing layer 23.

At operation S55, a display part 25 is formed. The touch screen panel 25a of a display part 25 is formed on a rear surface of the shielding printing layer 24.

The display part 25 is formed of an LCD 25b including a touch screen panel 25a, and the touch screen panel 25a may be any one of a film electrode type (GFF) TSP, a hybrid cover glass integrated (G1F) TSP, a cover glass integrated (G2) TSP, an OCTA touch screen panel, and/or the like.

The cover glass integrated (G2) TSP corresponds to a method of depositing a two-layered X and Y axis ITO pattern film on a rear surface of a window at a high temperature of 230 degrees or higher to realize a touch.

For example, because the window part 21 and the touch screen panel 25a are attached to each other at a high temperature in the cover glass integrated (G2) TSP, a pattern film layer 3 according to the related art is transversely changed, contracted, and short-circuited due to high temperature heat and a shape thereof is changed.

Because there is no such pattern film layer 3 according to the related art in the embodiment of the present disclosure, the above-mentioned disadvantages caused by a high temperature do not occur when the window part 21 and the touch screen panel 25a are attached to each other at a high temperature. Thus, the embodiment of the present disclosure may be applied to various types of touch screen panels 25a.

Hereinafter, a display device according to a third embodiment of the present disclosure will be described with reference to FIG. 6. In a description of the display device according to the third embodiment of the present disclosure, the same configurations as those of the display device according to the first embodiment of the present disclosure will be omitted and only differences between the third embodiment of the present disclosure and the first embodiment of the present disclosure will be described.

FIG. 6 is a view showing a configuration of a display device according to a third embodiment of the present disclosure.

Referring to FIG. 6, configuration of the display device will be described. The display device 30 includes a window part 31 formed of tempered glass, a deposition layer 32, a color printing layer 33, a shielding printing layer 34, and a display part 35. A three-dimensional pattern 31a may be formed on a rear surface of the window part 31 by etching the window part 21 by using a laser instead of a pattern film layer 3 according to the related art (see FIG. 1). The deposition layer 32 is formed between the window part 31 and the color printing layer 33 such that the color printing layer 33 is deposited on a three-dimensional pattern 31a formed a rear surface of the window part 31. The color printing layer 33 is formed on a rear surface of the deposition layer 32 such that the window part 31 may emit a luxurious and soft feeling by providing the window part 31 and the three-dimensional pattern 31a with various colors. The shielding printing layer 34 is formed on a rear surface of the color printing layer 33 to support the color printing layer 33 and the three-dimensional pattern 31a. The display part 35 is provided on a rear surface of the color printing layer 33 and on a lower surface of the window part 31 such that a screen of the display part 35 may be protected by the window part 31.

The display part 35 may be any one of an LCD 35b including a touch screen panel 35a and an LCD 35b without the touch screen panel 35a. An LCD 35b including the touch screen panel 35a according to various embodiments of the present disclosure will be described as an example.

The touch screen panel 35a may be any one of a film electrode type (GFF) TSP, a hybrid cover glass integrated (G1F) TSP, a cover glass integrated (G2) TSP, an OCTA touch screen panel, and/or the like.

Because detailed operations of the disclosed touch screen panels are the same as those of the first embodiment of the present disclosure, a description thereof will be omitted.

In this way, by forming the three-dimensional pattern 31a through etching on a rear surface of the window part 31 instead of the pattern film layer 3 according to the related art (see FIG. 1) and attaching the color printing layer 33 on a rear surface of the window part 31 by the deposition layer 32, a deep and three-dimensional feeling of a product can be realized, an external design of the product can become more appealing, and manufacturing costs can be reduced. Further, because a process for the pattern film layer 3 according to the related art (see FIG. 1) is not necessary, a manufacturing process of the product can be simplified and processing time can be reduced.

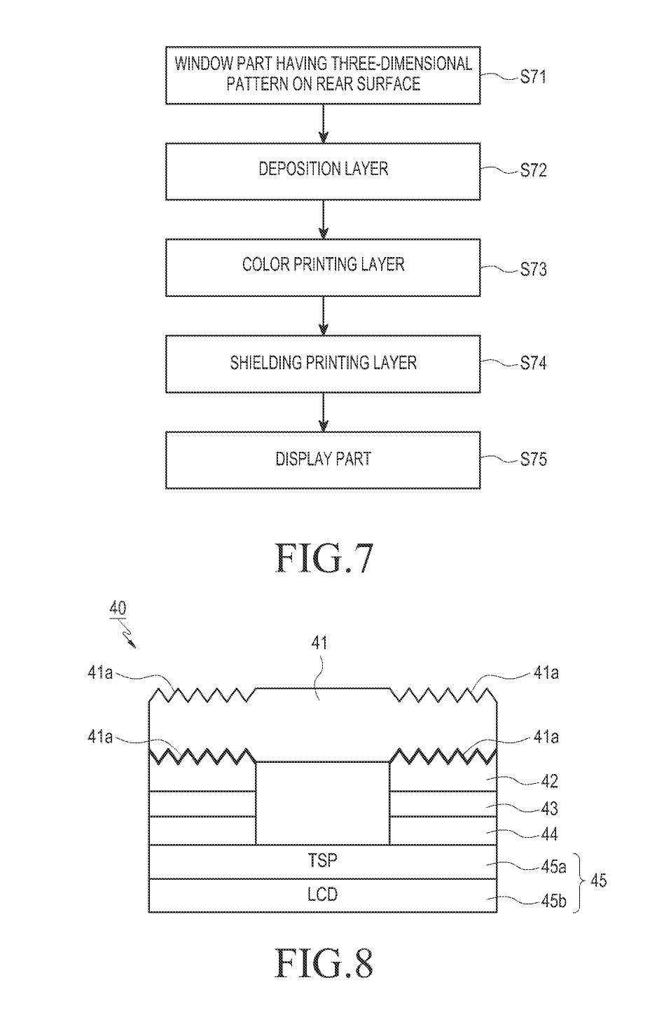

FIG. 7 is a flowchart showing a method of manufacturing a display device according to the third embodiment of the present disclosure.

Referring to FIG. 7, a method of manufacturing the display device will be described. A part 31 formed of tempered glass is manufactured.

At operation S71 a window part having a three-dimensional pattern 31a is formed. The three-dimensional pattern 31a is formed on a front surface of the window part 31 through etching instead of the pattern film layer 3 according to the related art (see FIG. 1). For example, three-dimensional pattern is formed in the window part 31 without using the pattern film layer according to the related art.

According to various embodiments of the present disclosure, the three-dimensional pattern 31a may have a saw-tooth shape having ridges and furrows and a zigzag pattern, and/or the like.

At operation S72, a deposition layer 32 is formed. The deposition layer 32 is formed on the three-dimensional pattern 31a formed on a rear surface of the window part 31.

At operation S73 a color printing layer 33 is formed. The color printing layer 33 is attached on a rear surface of the deposition layer 32.

For example, the deposition layer 32 is additionally formed and the color printing layer 33 may be attached to the three-dimensional pattern 31a formed on the rear surface of the window part 31 at the same time in the embodiment of the present disclosure.

At operation S74, a shielding printing layer 34 is formed. The shielding printing layer 34 is formed on a rear surface of the printing layer 33.

At operation S75, a display part 35 is formed. The touch screen panel 35a of a display part 35 is formed on a rear surface of the shielding printing layer 34.

The display part 35 is an LCD 35b including a touch screen panel 35a, and the cover glass integrated (G2) TSP corresponds to a method of depositing a two-layered X and Y axis ITO pattern film on a rear surface of the window part at a high temperature of 230 degrees or higher to realize a touch sensor.

For example, because the window part 31 and the touch screen panel are attached to each other at a high temperature in the cover glass integrated (G2) TSP, a pattern film layer 3 according to the related art is transversely changed, contracted, and short-circuited due to high temperature heat and a shape thereof is changed.

Because there is no such pattern film layer 3 according to the related art in the embodiment of the present disclosure, the above-mentioned disadvantages caused by high temperature heat do not occur when the window part 31 and the touch screen panel 35a are attached to each other at a high temperature. Thus, the embodiment of the present disclosure may be applied to various types of touch screen panels 35a.

Hereinafter, a display device according to a fourth embodiment of the present disclosure will be described with reference to FIG. 8. In a description of the display device according to the fourth embodiment of the present disclosure, the same configurations as those of the display device according to the first embodiment of the present disclosure will be omitted and only differences between the fourth embodiment of the present disclosure and the first embodiment of the present disclosure will be described.

FIG. 8 is a view showing a configuration of a display device according to a fourth embodiment of the present disclosure.

Referring to FIG. 8, a configuration of the display device will be described. The display device 40 includes a window part 41 formed of tempered glass, a deposition layer 42, a color printing layer 43, a shielding printing layer 44, and a display part 45. A three-dimensional pattern 41a may be formed on the front and rear surfaces of the window part 41 by etching the window part 21 by using a laser instead of a pattern film layer 3 according to the related art (see FIG. 1). Thus, it is unnecessary to separately form a pattern film layer 3 according to the related art (see FIG. 1) in the window part 41. In this way, by forming three-dimensional patterns on both the front and rear surfaces of the window part 41 without using the pattern film layer according to the related art, the thickness of a product can be reduced, manufacturing costs can be reduced, and processing can be simplified.

As illustrated in FIG. 8, the deposition layer 42 is formed between the window part 41 and the color printing layer 43 such that the color printing layer 43 is deposited on a three-dimensional pattern 41a formed a rear surface of the window part 41. The color printing layer 43 is attached on a rear surface of the deposition layer 42 such that the window part 41 may emit a luxurious and soft feeling by providing the window part 41 and the three-dimensional pattern 41a with various colors. The shielding printing layer 44 is formed on a rear surface of the color printing layer 43 to support the color printing layer 43 and the three-dimensional pattern 41a. The display part 45 is provided on a rear surface of the color printing layer 43 and on a lower surface of the window part 41 such that a screen of the display part 45 may be protected by the window part 41.

The display part 45 may be any one of an LCD 45b including a touch screen panel 45a and an LCD 45b without the touch screen panel 45a. In the embodiment of the present disclosure, the LCD 45b including the touch screen panel 45a will be described as an example.

The touch screen panel 45a may be any one of a film electrode type (GFF) TSP, a hybrid cover glass integrated (G1F) TSP, a cover glass integrated (G2) TSP, an OCTA touch screen panel, and/or the like.

Because detailed operations of the disclosed touch screen panels 45a are the same as those of the first embodiment of the present disclosure, a description thereof will be omitted.

In this way, by forming the three-dimensional pattern 41a through etching on both the front and rear surfaces of the window part 41 instead of the pattern film layer 3 according to the related art (see FIG. 1) and attaching the color printing layer 43 on a rear surface of the window part 41 by the deposition layer 42, a deep and three-dimensional feeling of a product can be realized, an external design of the product can become more appealing, and manufacturing costs can be reduced. Further, because a process for the pattern film layer 3 according to the related art (see FIG. 1) is not necessary, a manufacturing process of the product can be simplified and processing time can be reduced. In addition, by forming the three-dimensional pattern 41a on the front and rear surfaces of the window part 41 instead of a rear surface of the window part 41, the method can be applied to various types of touch screen panels 45a other than the disclosed touch screen panel 45a.

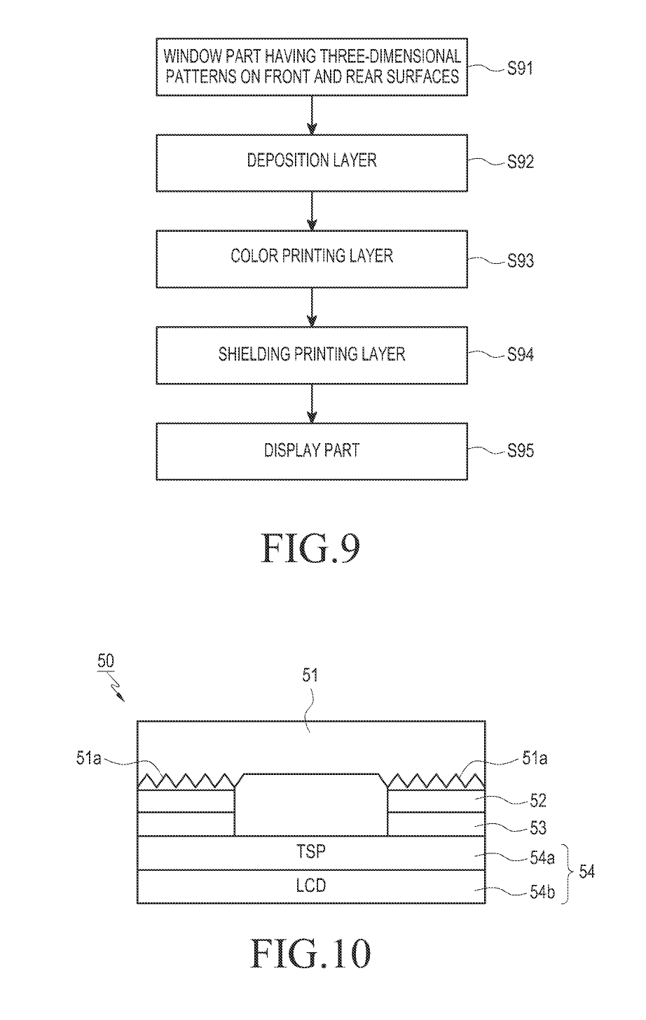

FIG. 9 is a flowchart showing a method of manufacturing a display device according to the fourth embodiment of the present disclosure.

Referring to FIG. 9, a method of manufacturing the display device will be described. A window part 41 formed of tempered glass is manufactured.

At operation S91, a window part having three dimensional patterns 41a on the front surface and the rear surface is formed. The three-dimensional patterns 41a are formed on both the front and rear surfaces of the window part 41 through etching (S1). For example, the three-dimensional pattern 41a is formed instead of the pattern film layer 3 according to the related art (see FIG. 1). Thus, a process of providing the pattern film layer 3 according to the related art is not necessary.

According to various embodiments of the present disclosure, the three-dimensional pattern 41a may have a saw-tooth shape having ridges and furrows and a zigzag pattern, and/or the like.

At operation S92, a deposition layer 42 is formed. The deposition layer 42 is formed on a three-dimensional pattern 41a formed on a rear surface of the window part 41 having the three-dimensional pattern 41a.

At operation S93, a color printing layer 43 is formed. The color printing layer 43 is attached on a rear surface of the deposition layer 42.

At operation S94, a shielding printing layer 44 is formed. The shielding printing layer 44 is formed on a rear surface of the printing layer 43.

At operation S95, a display part 45 is formed. The touch screen panel 45a of a display part 45 is formed on a rear surface of the shielding printing layer 44.

The display part 45 is formed of an LCD 45b including a touch screen panel 45a, and the touch screen panel 45a may be any one of a film electrode type (GFF) TSP, a hybrid cover glass integrated (G1F) TSP, a cover glass integrated (G2) TSP, an OCTA touch screen panel, and/or the like.

For example, because the window part 41 and the touch screen panel 45a are attached to each other at a high temperature in the cover glass integrated (G2) TSP, a pattern film layer according to the related art 3 (see FIG. 1) is transversely changed, contracted, and short-circuited due to high temperature heat and a shape thereof is changed.

Because there is no such pattern film layer 3 according to the related art on a front surface or a rear surface of the window part 41 in the embodiment of the present disclosure, the above-mentioned disadvantages do not occur when the window part 41 and the touch screen panel 45a are attached to each other at a high temperature. Thus, the embodiment of the present disclosure may be applied to various types of touch screen panels 45a.

Hereinafter, a display device according to a fifth embodiment of the present disclosure will be described with reference to FIG. 10. In a description of the display device according to the fifth embodiment of the present disclosure, the same configurations as those of the display device according to the first embodiment of the present disclosure will be omitted and only differences between the fifth embodiment of the present disclosure and the first embodiment of the present disclosure will be described.

FIG. 10 is a view showing a configuration of a display device according to a fifth embodiment of the present disclosure.

Referring to FIG. 10, a configuration of the display device will be described. The display device 50 includes a window part 51 formed of tempered glass, a color printing layer 52, a shielding printing layer 53, and a display part 54. A three-dimensional pattern 51a is etched on a rear surface of the window part 51 by using a laser. For example, the three-dimensional pattern 51a may be used instead of the pattern film layer 3 according to the related art (see FIG. 3). Thus, it is unnecessary to separately form a pattern film layer 3 according to the related art (see FIG. 1).

As illustrated in FIG. 10, the color printing layer 52 is formed on a rear surface of the window part 51 such that the window part 51 may emit a luxurious and soft feeling by providing the window part 51 and the three-dimensional pattern 51a with various colors. The shielding printing layer 53 is formed on a rear surface of the color printing layer 52 to support the color printing layer 52 and the three-dimensional pattern 51a. The display part 54 is provided on a rear surface of the color printing layer 52 and on a lower surface of the window part 51 such that a screen of the display part 54 may be protected by the window part 51.

For example, the display part 54 may be any one of an LCD 54b including a touch screen panel 54a and an LCD 54b without the touch screen panel 54a. The LCD 54b including the touch screen panel 54a according to an embodiment of the present disclosure will be described as an example.

Because detailed operations of the disclosed touch screen panels 54a are the same as those of the first embodiment of the present disclosure, a description thereof will be omitted.

In this way, by forming a three-dimensional pattern 51a on a rear surface of the window part 51 through etching instead of forming a pattern film layer according to the related art, a deep and three-dimensional feeling of a product may be realized, an external design of the product may become appealing, manufacturing costs of the product may be reduced, and a manufacturing process of the product may be simplified and processing time may be reduced as a separate pattern film layer attaching process according to the related art is not necessary.

A color printing layer 52 may be directly attached to the three-dimensional pattern 51a formed on a rear surface of the window part 51 without using a deposition layer separately.

According to various embodiments of the present disclosure, three-dimensional pattern 51a may have a saw-tooth shape having ridges and furrows and a zigzag pattern, and/or the like. Of course, other shapes and patterns may be applied as the three-dimensional pattern 51a in addition to the disclosed shapes and patterns.

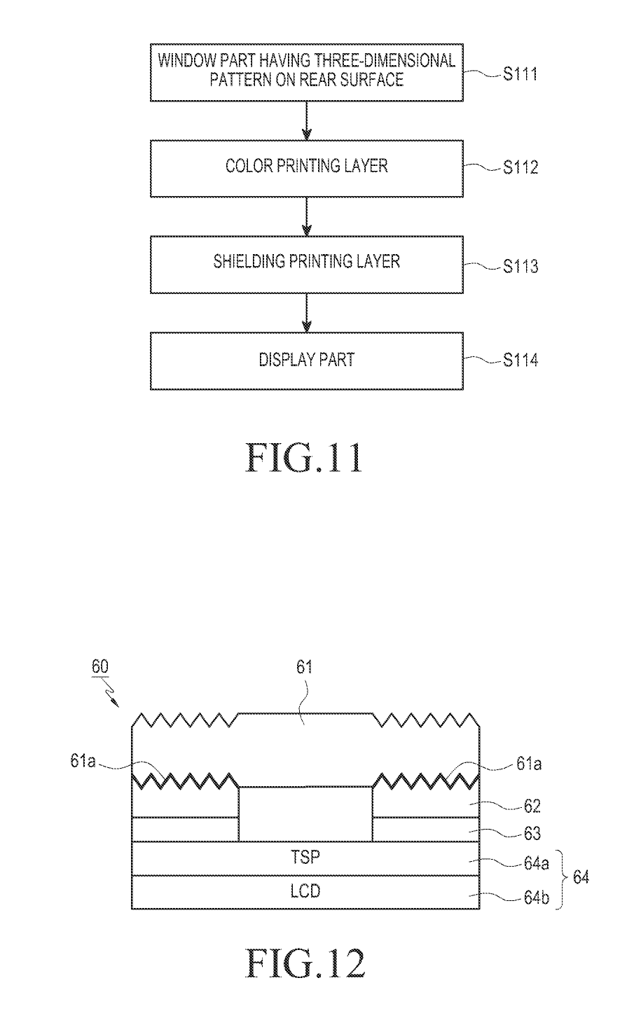

FIG. 11 is a flowchart showing a method of manufacturing a display device according to the fifth embodiment of the present disclosure.

Referring to FIG. 11, a method of manufacturing the display device 50 will be described. A window part 51 formed of tempered glass is manufactured.

At operation S111 a window part having three-dimensional pattern 51a formed on a rear surface thereof is formed. The three-dimensional pattern 51a is formed on a front surface of the window part 51 through etching instead of the pattern film layer 3 according to the related art (see FIG. 1). Thus, a three-dimensional pattern 51a is formed on a front surface of the window part 51 through etching instead of the pattern film layer 3 according to the related art (see FIG. 1).

According to various embodiments of the present disclosure, the three-dimensional pattern 51a has a saw-tooth shape having ridges and furrows and a zigzag pattern, and/or the like.

At operation S112, a color printing layer 52 is formed. The color printing layer 52 is formed on a rear surface of the window part 51 having the three-dimensional pattern 51a without using a separate deposition layer.

At operation S113, a shielding printing layer 53 is formed. The shielding printing layer 53 is formed on a rear surface of the printing layer 52.

At operation S114, a display part 54 is formed. The touch screen panel 54a of a display part 54 is formed on a rear surface of the shielding printing layer 53.

The display part 54 is formed of an LCD 25b including a touch screen panel 54a, and the touch screen panel 54a may be any one of a film electrode type (GFF) TSP, a hybrid cover glass integrated (G1F) TSP, a cover glass integrated (G2) TSP, an OCTA touch screen panel, and/or the like.

Because the window part 51 and the touch screen panel 54a are attached to each other at a high temperature in the cover glass integrated (G2) TSP, a pattern film layer 3 according to the related art (see FIG. 1) is transversely changed, contracted, and short-circuited due to high temperature heat and a shape thereof is changed.

Because there is no such pattern film layer 3 according to the related art in the embodiment of the present disclosure, the above-mentioned disadvantages caused by high temperature heat do not occur when the window part 51 and the touch screen panel 54a are attached to each other at a high temperature. Thus, the embodiment of the present disclosure may be applied to various types of touch screen panels 54a.

Hereinafter, a display device according to a sixth embodiment of the present disclosure will be described with reference to FIG. 12. In a description of the display device according to an embodiment of the present disclosure, the same configurations as those of the display device according to the first embodiment of the present disclosure will be omitted and only differences between the sixth embodiment of the present disclosure and the first embodiment of the present disclosure will be described.

FIG. 12 is a view showing a configuration of a display device according to a sixth embodiment of the present disclosure.

Referring to FIG. 12, a configuration of the display device 60 will be described. The display device 60 includes a window part 61 formed of tempered glass, a color printing layer 62, a shielding printing layer 63, and a display part 64. A three-dimensional pattern 61a may be formed on front and rear surfaces of the window part 61 by etching the window part 61 by using a laser instead of a pattern film layer 3 according to the related art (see FIG. 1). For example, by forming the three-dimensional patterns on the front and rear surfaces of the window part without using the pattern film layer according to the related art separately, the thickness of a product can be further reduced, manufacturing costs can be reduced, and processing can be simplified.

As illustrated in FIG. 12, the color printing layer 62 is formed on a rear surface of the window part 61 such that the window part 61 may show a luxurious and soft feeling by providing the window part 61 and the three-dimensional pattern 61a with various colors. The shielding printing layer 63 is formed on a rear surface of the color printing layer 62 to support the color printing layer 62 and the three-dimensional pattern 61a. The display part 64 is provided on a rear surface of the color printing layer 62 and on a lower surface of the window part 61 such that a screen of the display part 64 may be protected by the window part 61.

The display part 64 may be any one of an LCD 64b including a touch screen panel 64a and an LCD 64b without the touch screen panel 64a. The LCD 64b including the touch screen panel 64a according to an embodiment of the present disclosure will be described as an example.

Because detailed operations of the disclosed touch screen panels 64a are the same as those of the first embodiment of the present disclosure, a description thereof will be omitted.

In this way, by forming a three-dimensional pattern 61a on front and rear surfaces of the window part 61 instead of forming a pattern film layer according to the related art, a depth and a three-dimensional feeling of a product may be realized, an external design of the product may become appealing, manufacturing costs of the product may be reduced, the thickness of the product can be reduced, and a manufacturing process of the product may be simplified and processing time may be reduced as a separate pattern film layer attaching process according to the related art is not necessary.

A color printing layer 62 may be directly attached to the three-dimensional pattern 61a formed on a rear surface of the window part 61 without using a deposition layer separately.

According to various embodiments of the present disclosure, three-dimensional pattern 61a may have a saw-tooth shape having ridges and furrows and a zigzag pattern, and/or the like. Of course, other shapes and patterns may be applied as the three-dimensional pattern 61a in addition to the disclosed shapes and patterns.

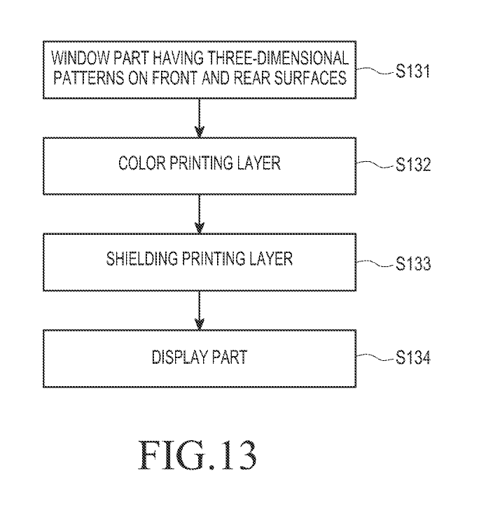

FIG. 13 is a flowchart showing a method of manufacturing a display device according to the sixth embodiment of the present disclosure.

Referring to FIG. 13, a method of manufacturing the display device 60 will be described. A window part 61 formed of tempered glass is manufactured.

At operation S131, a window part having three-dimensional patterns 61a formed on a front surface and a rear surface thereof is formed. The three-dimensional patterns 61a are formed on both the front and rear surfaces of the window part 61 through etching.

For example, the three-dimensional patterns 61a are formed instead of the pattern film layer according to the related art. Thus, because the pattern film layer according to the related art is not necessary, a manufacturing process for a product can be simplified, and manufacturing costs and a process time can be reduced.

According to various embodiments of the present disclosure, the three-dimensional pattern 61a has a saw-tooth shape having ridges and furrows and a zigzag pattern, and/or the like.

At operation S132, a color printing layer 62 is formed. The color printing layer 62 is formed on a rear surface of the window part 61 having the three-dimensional pattern 61a without using a separate deposition layer.

At operation S133, a shielding printing layer 63 is formed. The shielding printing layer 63 is formed on a rear surface of the printing layer 62.

At operation S134 a display part 64 is formed. The touch screen panel 64a of a display part 64 is formed on a rear surface of the shielding printing layer 63.

The display part 64 is formed of an LCD 64b including a touch screen panel 64a, and the touch screen panel 64a may be any one of a film electrode type (GFF) TSP, a hybrid cover glass integrated (G1F) TSP, a cover glass integrated (G2) TSP, an OCTA touch screen panel, and/or the like.

Because the window part 61 and the touch screen panel 64a are attached to each other at a high temperature in the cover glass integrated (G2) TSP, a pattern film layer 3 according to the related art (see FIG. 1) is transversely changed, contracted, and short-circuited due to high temperature heat and a shape thereof is changed.

Because there is no such pattern film layer 3 according to the related art (see FIG. 1) in the embodiment of the present disclosure, the above-mentioned disadvantages do not occur when the window part 61 and the touch screen panel 64a are attached to each other at a high temperature. Thus, the embodiment of the present disclosure may be applied to various types of touch screen panels 64a.

The display devices 10, 20, 30, 40, 50, and 60 according to the various embodiments of the present disclosure may be applied to a portable communication device. However, the present disclosure is not limited to a portable communication device, but may be applied to various types of electronic devices (e.g., a TV, a notebook, a monitor, and/or the like).

While the present disclosure has been shown and described with reference to various embodiments thereof, it will be understood by those skilled in the art that various changes in form and details may be made therein without departing from the spirit and scope of the present disclosure as defined by the appended claims and their equivalents.

1. A display device comprising:
a window part having a three-dimensional pattern on a front surface thereof;
a color printing layer formed on a rear surface of the window part;
a shielding printing layer formed on a rear surface of the color printing layer; and
a display part provided on a rear surface of the shielding printing layer.

2. The display device of claim 1, wherein the three dimensional pattern is used on the front surface of the window part instead of a pattern film layer.

3. The display device of claim 1, wherein the three-dimensional pattern is etched on the front surface of the window part.

4. The display device of claim 1, wherein the display part is any one of a Liquid Crystal Display (LCD) and a Light Emitting Diode (LED), and includes a touch screen panel.

5. The display device of claim 4, wherein the touch screen panel is any one of a film electrode type (GFF) Touch Screen Panel (TSP), a hybrid cover glass integrated (G1F) TSP, a cover glass integrated (G2) 14a TSP, and an On-Cell Touch Active Matrix Organic Light Emitting Diode (AMOLED) (OCTA) TSP.

6. The display device of claim 1, wherein the three-dimensional pattern has a saw-tooth shape.

7. The display of claim 6, wherein the saw-tooth shape comprises ridges and furrows.

8. The display device of claim 1, wherein the three-dimensional pattern has a zigzag pattern.

9. The display device of claim 1, wherein the window part is formed of at least one of tempered glass, reinforced plastic, reinforced acryl, and polycarbonate.

10. The display device of claim 1, wherein the color printing layer is formed on the rear surface of the window part such that a pattern layer does not reside between the window part and the color printing layer.

11. A method of manufacturing a display device, the method comprising:
forming a three-dimensional pattern on a front surface of a window part;
forming a color printing layer on a rear surface of the window part;
forming a shielding printing layer on a rear surface of the color printing layer; and
providing a display device on a rear surface of the shielding printing layer.

12. The method of claim 11, wherein the three dimensional pattern is used on the front surface of the window part instead of a pattern film layer.

13. The method of claim 11, wherein the three-dimensional pattern is etched on the front surface of the window part by using a laser.

14. The method of claim 11, wherein the display part is any one of a Liquid Crystal Display (LCD) and a Light Emitting Diode (LED), and includes a touch screen panel.

15. The method of claim 14, wherein the touch screen panel is any one of a film electrode type (GFF) Touch Screen Panel (TSP), a hybrid cover glass integrated (G1F) TSP, a cover glass integrated (G2) 14a TSP, and an On-Cell Touch Active Matrix Organic Light Emitting Diode (AMOLED) (OCTA) TSP.

16. The method of claim 11, wherein the window part is formed of at least one of tempered glass, reinforced plastic, reinforced acryl, and polycarbonate.

17. The method of claim 11, wherein the color printing layer is formed on the rear surface of the window part such that a pattern layer does not reside between the window part and the color printing layer.

18. A display device comprising:
a window part having a three-dimensional pattern on a front surface thereof;
a deposition layer provided on a rear surface of the window part;
a color printing layer formed on a rear surface of the deposition layer;
a shielding printing layer formed on a rear surface of the color printing layer; and
a display part provided on a rear surface of the shielding printing layer.

19. The display device of claim 18, wherein the three dimensional pattern is used on the front surface of the window part instead of a pattern film layer.

20. The display device of claim 18, wherein the three-dimensional pattern is etched on the front surface of the window part.

21. The display device of claim 18, wherein the deposition layer is formed on the rear surface of the window part such that a film layer does not reside between the window part and the deposition layer.

22. A method of manufacturing a display device, the method comprising:
forming a three-dimensional pattern on a front surface of a window part;
forming a deposition layer on a rear surface of the window part;
forming a color printing layer on a rear surface of the deposition layer;
forming a shielding printing layer on a rear surface of the color printing layer; and
providing a display device on a rear surface of the shielding printing layer.

23. The method of claim 22, wherein the three dimensional pattern is used on the front surface of the window part instead of a pattern film layer.

23. The method of claim 22, wherein the deposition layer is formed on the rear surface of the window part such that a film layer does not reside between the window part and the deposition layer.

24. A display device comprising:
a window part having a three-dimensional pattern on a rear surface thereof;
a deposition layer provided on a rear surface of the window part;
a color printing layer formed on a rear surface of the deposition layer;
a shielding printing layer formed on a rear surface of the color printing layer; and
a display part provided on a rear surface of the shielding printing layer.

25. The display device of claim 24, wherein the three dimensional pattern is used on the rear surface of the window part instead of a pattern film layer.

26. The display device of claim 24, wherein the three-dimensional pattern is etched on the rear surface of the window part.

27. The display device of claim 24, wherein the deposition layer is formed on the rear surface of the window part such that a film layer does not reside between the window part and the deposition layer.

28. A method of manufacturing a display device, the method comprising:
forming a three-dimensional pattern on a rear surface of a window part;
forming a deposition layer on a rear surface of the window part;
forming a color printing layer on a rear surface of the deposition layer;
forming a shielding printing layer on a rear surface of the color printing layer; and
providing a display device on a rear surface of the shielding printing layer.

29. The method of claim 28, wherein the three dimensional pattern is used on the rear surface of the window part instead of a pattern film layer.

30. The method of claim 28, wherein the deposition layer is formed on the rear surface of the window part such that a film layer does not reside between the window part and the deposition layer.

31. A display device comprising:
a window part having three-dimensional patterns on front and rear surfaces thereof;
a deposition layer provided on a rear surface of the window part;
a color printing layer formed on a rear surface of the deposition layer;
a shielding printing layer formed on a rear surface of the color printing layer; and
a display part provided on a rear surface of the shielding printing layer.

32. The display device of claim 31, wherein the three dimensional patterns are used on the front and rear surfaces of the window part instead of a pattern film layer.

33. The display device of claim 31, wherein the three-dimensional patterns are etched on the front and rear surfaces of the window part.

34. The display device of claim 31, wherein the deposition layer is formed on the rear surface of the window part such that a film layer does not reside between the window part and the deposition layer.

35. A method of manufacturing a display device, the method comprising:
forming three-dimensional patterns on front and rear surfaces of a window part;
forming a deposition layer on a rear surface of the window part;
forming a color printing layer on a rear surface of the deposition layer;
forming a shielding printing layer on a rear surface of the color printing layer; and
providing a display device on a rear surface of the shielding printing layer.

36. The method of claim 35, wherein the three dimensional patterns are used on the front and rear surfaces of the window part instead of a pattern film layer.

37. The method of claim 35, wherein the deposition layer is formed on the rear surface of the window part such that a film layer does not reside between the window part and the deposition layer.

38. A display device comprising:
a window part having a three-dimensional pattern on a rear surface thereof;
a color printing layer formed on a rear surface of the window part;
a shielding printing layer formed on a rear surface of the color printing layer; and
a display part provided on a rear surface of the shielding printing layer.

39. The display device of claim 38, wherein the three dimensional pattern is used on the rear surface of the window part instead of a pattern film layer.

40. The display device of claim 38, wherein the three-dimensional pattern is etched on the rear surface of the window part.

41. The display device of claim 38, wherein the color printing layer is formed on the rear surface of the window part such that a pattern layer does not reside between the window part and the color printing layer.

42. A method of manufacturing a display device, the method comprising:
forming a three-dimensional pattern on a rear surface of a window part;
forming a color printing layer on a rear surface of the window part;
forming a shielding printing layer on a rear surface of the color printing layer; and
providing a display device on a rear surface of the shielding printing layer.

43. The method of claim 42, wherein the three dimensional pattern is used on the rear surface of the window part instead of a pattern film layer.

44. The method of claim 42, wherein the color printing layer is formed on the rear surface of the window part such that a pattern layer does not reside between the window part and the color printing layer.

45. A display device comprising:
a window part having a three-dimensional pattern on front and rear surfaces thereof;
a color printing layer formed on a rear surface of the window part;
a shielding printing layer formed on a rear surface of the color printing layer; and
a display part provided on a rear surface of the shielding printing layer.

46. The display device of claim 45, wherein the three dimensional patterns are used on the front and rear surfaces of the window part instead of a pattern film layer.

47. The display device of claim 45, wherein the three-dimensional patterns are etched on the front and rear surfaces of the window part.

48. The display device of claim 45, wherein the color printing layer is formed on the rear surface of the window part such that a pattern layer does not reside between the window part and the color printing layer.

49. A method of manufacturing a display device, the method comprising:
forming three-dimensional patterns on front and rear surfaces of a window part;
forming a color printing layer on a rear surface of the window part;
forming a shielding printing layer on a rear surface of the color printing layer; and
providing a display device on a rear surface of the shielding printing layer.

50. The method of claim 38, wherein the three dimensional patterns are used on the front and rear surfaces of the window part instead of a pattern film layer.

51. The method of claim 49, the color printing layer is formed on the rear surface of the window part such that a pattern layer does not reside between the window part and the color printing layer.
